(19) United States
(12) Patent Application Publication
(10) Pub. No.: US 2026/0279745 A1
(43) Pub. Date: Sep. 17, 2026

(54) CLEANCOAT AND RELATED METHODS FOR SUBSTRATE PROCESSING CHAMBERS

(71) Applicant: Applied Materials, Inc., Santa Clara, CA (US)

(72) Inventors: He LI, Santa Clara, CA (US); Yao XU, Santa Clara, CA (US); Zhen LIU, San Jose, CA (US); Tsung-Han YANG, San Jose, CA (US); Xi CEN, San Jose, CA (US); Kai WU, Palo Alto, CA (US); Rongjun WANG, Dublin, CA (US)

(21) Appl. No.: 19/562,397

(22) Filed: Mar. 10, 2026

Related U.S. Application Data
(60) Provisional application No. 63/770,621, filed on Mar. 12, 2025.

(51) Int. Cl. H01J 37/32; B08B 7/00; C23C 16/14; C23C 16/44; C23C 16/50; H10P 72/76

(52) U.S. Cl. CPC H01J 37/32862; B08B 7/0035; C23C 16/14; C23C 16/4404; C23C 16/4405; C23C 16/50; H01J 37/3244; H01J 37/32486; H10P 72/7616; H01J 2237/3321

(57) ABSTRACT

An embodiment of a method includes (a) cleaning one or more interior surfaces of a substrate processing chamber. In addition, the method includes (b) depositing a coating on the one or more interior surfaces by use of a plasma-enhanced vapor deposition (PECVD) process after (a) to reduce peeling of residue that is subsequently deposited on the coating.

### CROSS-REFERENCE TO RELATED APPLICATIONS

This application claims priority to and the benefit of United States provisional patent application Ser. No. 63/770,621, filed Mar. 12, 2025 and entitled “Cleancoat and Related Methods for Substrate Processing Chambers,” the entire contents of which are incorporated herein by reference.

### BACKGROUND

Embodiments described herein generally relate to substrate processing chambers, and more particularly to methods for cleaning and coating one or more internal surfaces or components of a substrate processing chamber to reduce metal contamination and increase chamber throughput.

As a part of a fabrication process for a semiconductor device, such as an integrated circuit, one or more deposition processes may be performed in which films, such as metals or dielectric films, are deposited onto the surface of the substrate (or another surface, device, or film positioned thereon). Example deposition processes may include, for example, atomic layer deposition (ALD), chemical vapor deposition (CVD), physical vapor deposition (PVD), or a plasma-enhanced variant thereof.

### SUMMARY

Some embodiments disclosed herein are directed to a method including (a) cleaning one or more interior surfaces of a substrate processing chamber. In addition, the method includes (b) depositing a coating on the one or more interior surfaces by use of a plasma-enhanced vapor deposition (PECVD) process after (a) to reduce peeling of residue that is subsequently deposited on the coating.

Some embodiments disclosed herein are directed to a method including (a) performing a deposition process in a processing chamber in which a material is deposited onto a surface of a substrate and additional material is deposited on one or more interior surfaces of the processing chamber as residue. In addition, the method includes (b) removing the substrate from the processing chamber after (a). Further, the method includes (c) cleaning the residue off of the one or more interior surfaces by use of a radical after (b). Still further, the method includes (d) depositing a coating on the one or more interior surfaces by use of a plasma-enhanced vapor deposition (PECVD) process after (c).

Some embodiments disclosed herein are directed to a method including (a) depositing a first molybdenum (Mo) coating on one or more interior surfaces of a processing chamber by use of a first plasma-enhanced vapor deposition (PECVD) process. In addition, the method includes (b) performing one or more deposition processes in the processing chamber in which a material is deposited onto a surface of a substrate and additional material is deposited on the first Mo coating as a residue. Further, the method includes (c) removing the residue and the first Mo coating from the one or more interior surfaces of the processing chamber by use of a radical after (b). Still further, the method includes (d) depositing a second Mo coating on the one or more interior surfaces after (c), by use of a second PECVD process.

### BRIEF DESCRIPTION OF THE DRAWINGS

For a detailed description of various exemplary embodiments, reference will now be made to the accompanying drawings in which:

FIG. 1 is a schematic diagram of a processing chamber for performing a deposition process on a substrate and for performing a cleaning and coating method for one or more interior surfaces according to one or more embodiments disclosed herein; and

FIG. 2 is a flow diagram of a method of cleaning and coating one or more surfaces of a processing chamber according to one or more embodiments disclosed herein.

### DETAILED DESCRIPTION

A processing chamber may be configured to deposit materials (e.g., metals, dielectric materials, etc.) on a substrate, such as a semiconductor wafer or other substrate. The deposition process may be performed in an enclosed processing chamber and may not only result in the deposition of materials on the substrate, but also on the inner walls of the processing chamber or other components positioned therein. Such additional deposited materials or films (that is, not on the substrate) may be broadly referred to herein as “residue.” This residue builds up as more substrates are processed in the processing chamber and leads to the generation of particles and other contaminants. Specifically, the residue may have poor adhesion and often exerts higher inner stresses (e.g., compressive stresses) on an underling surface. Without being limited to this or any other theory, a high stress in an accumulated residue (or other coating or film) on the underlying surface may increase an interstitial force between the coating and underlying surface that may ultimately lead to buckling of the residue and separation of thereof from the underlying surfaces. This buckling and separation may be further exacerbated by thermal gradients that may be generated within the processing chamber during substrate processing. As a result, the deposited residue within a processing chamber may peel and potentially fall onto the substrate during processing operations, which may result in damage or at least contamination (e.g., metal contamination) of the substrate.

Accordingly, embodiments disclosed herein include methods for cleaning and coating the internal surfaces of a substrate processing chamber in order to reduce the risk of damage or contamination of a substrate due to peeling of residue deposited thereon. In some embodiments, a method described herein may include performing a cleaning operation within the processing chamber following a number of deposition operations for substrate. The cleaning operation may be configured to remove at least a portion (or all) of the residue that may have been deposited on the inner surface within the processing chamber during previous deposition operations. Following the cleaning operation, embodiments of the methods described herein may include coating the inner surfaces of the processing chamber via a plasma enhanced chemical vapor deposition (PECVD) process. In some embodiments, the coating formed by the PECVD process may exert a lower stress on the underlying surface or material so that subsequently deposited residue on the coating is less likely to peel and therefore cause damage or contamination to a substrate undergoing a deposition process in the processing chamber. Thus, through use of the embodiments disclosed herein, the risk of damage or contamination resulting from peeled residue in a substrate processing chamber may be reduced. In addition, embodiments disclosed herein may allow a substrate processing chamber to perform a greater number of deposition operations before an additional cleaning and coating operation according to the embodiments described herein is to be performed.

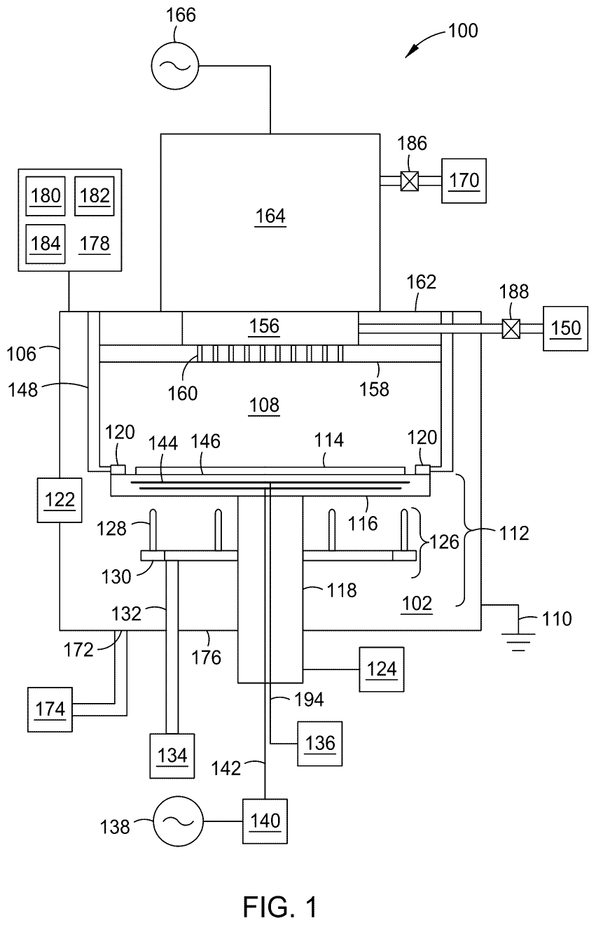

FIG. 1 shows an example processing chamber (or “chamber” or “substrate processing chamber”) 10 for performing a deposition operation, such as a plasma enhanced deposition operation, on a substrate 114 according to one or more embodiments disclosed herein. In some embodiments, the substrate 114 may comprise a semiconductor substrate, such as a semiconductor wafer, or other suitable substrate.

In some embodiments, the chamber 100 may include a remote plasma source (RPS) 164 in accordance with some embodiments. The chamber 100 may be a vacuum chamber that is adapted to maintain sub-atmospheric pressures within an interior volume 102 during substrate processing. In some embodiments, the chamber 100 can maintain a pressure of approximately 10 millitorr (mTorr) to approximately 200 mTorr. The chamber 100 includes a chamber body 106 which encloses a processing volume 108 located in the upper portion (e.g., such as the upper half) of the interior volume 102. The chamber body 106 may be made of metal, such as aluminum and the like. The chamber body 106 may be grounded via a coupling to ground 110.

A substrate support 112 is positioned within the interior volume 102 to support and retain the substrate 114, such as a semiconductor wafer, for example, or other such substrate. The substrate support 112 may generally comprise a pedestal 116 (or platen) and a hollow support shaft 118 for supporting the pedestal 116. The pedestal 116 may comprise an aluminum-based material or a ceramic-based material and the like. In some embodiments, the pedestal 116 may be formed of a ceramic-based material so as to be suitable for high temperature processes. The hollow support shaft 118 provides a conduit to provide, for example, backside gases, process gases, fluids, coolants, power, or the like, to the pedestal 116. In some embodiments, the substrate support 112 includes a focus ring 120 disposed about the pedestal 116 to enhance process uniformity at an edge of the substrate 114. In some embodiments, the focus ring 120 is made of quartz-based materials. In some embodiments, the focus ring 120 is made of ceramic-based materials. The ceramic-based material facilitates high pressure process capabilities. A slit valve 122 may be coupled to the chamber body 106 to facilitate transferring the substrate 114 into and out of the interior volume 102.

In some embodiments, the hollow support shaft 118 is coupled to a lift actuator 124, such as a motor, which is configured to move the pedestal 116 between an upper, processing position, and a lower, transfer position within the interior volume 102. A substrate lift 126 can include lift pins 128 mounted on a platform 130 connected to a shaft 132 which is coupled to a second lift actuator 134 for raising and lowering the substrate lift 126 so that the substrate 114 may be placed on or removed from the pedestal 116. The pedestal 116 may include through-holes to receive the lift pins 128. The hollow support shaft 118 provides a path for a gas conduit 194 for coupling a backside gas supply 136 and/or a radio frequency (RF) power supply 138 to the pedestal 116. In some embodiments, the RF power supply 138 provides bias power through a matching network 140 to the pedestal 116 via a power conduit 142. In some embodiments, RF energy supplied by the RF power supply 138 may have a frequency of about 2 Megahertz (MHz) or greater. In some embodiments, the RF power supply 138 may have a frequency of about 13.56 MHz.

In some embodiments, the backside gas supply 136 is positioned outside of the chamber body 106 and supplies gas to the pedestal 116. In some embodiments, the pedestal 116 includes a gas channel 144, allowing gas to interact with a backside of the substrate 114 to maintain a given temperature. The gas channel 144 is configured to provide backside gas, such as nitrogen (N₂), argon (Ar), or helium (He), to an upper surface 146 of the pedestal 116 to act as a heat transfer medium, and potentially as a purge medium to prevent or restrict material deposition on the backside of the substrate 114. The gas channel 144 is in fluid communication with the backside gas supply 136 via gas conduit 194 to control the temperature and/or temperature profile of the substrate 114 during use. For example, the backside gas supply 136 can supply gas to cool and/or heat the substrate 114 during use. In some embodiments, the substrate 114 may be heated from approximately 250 degrees Celsius (° C.) to approximately 500° C., such as from about 275° C. to about 420° C.; however, other temperature ranges are contemplated. In some embodiments, one or more heater elements (e.g., electrically resistive coils—not shown) may be coupled to or embedded into the pedestal 116 that are configured to heat the substrate 114 during operations.

The chamber 100 includes a process kit circumscribing various chamber components to prevent unwanted reaction between such components and contaminants. The process kit includes an upper shield 148. In some embodiments, the upper shield 148 may be made of metal, such as aluminum. In some embodiments, the process kit may be constructed of quartz. In some embodiments, a mixing reservoir 156 is coupled to and in fluid communication with the processing volume 108. The mixing reservoir 156 is also fluidly connected to the RPS 164. The mixing reservoir 156 allows mixing of the plasma gases with other gases provided by a gas delivery system 150. The gas delivery system 150 may include an ampoule that is used to supply a gas, such as a chlorine-based gas, and the like to the process volume 108. A flow rate of the other gases from the gas delivery system 150 may be controlled by a first flow valve 188.

A showerhead 158 is located above the processing volume 108 and below a ceiling 162 of the chamber body 106. The showerhead 158 includes through-holes 160 to flow gases from the mixing reservoir 156 into the processing volume 108. The RPS 164 is fluidly connected to the mixing reservoir 156 to allow ionized gases to flow from the RPS 164 into the mixing reservoir 156, through the showerhead 158, and into the processing volume 108. Plasma is generated in the RPS 164 by a plasma RF power source 166 that provides RF energy to the RPS 164. Process gases used to form the plasma are supplied by a process gas source 170 and controlled by a second flow valve 186. The plasma gases supplied by the process gas source 170 may include, but are not limited to, hydrogen, helium, and/or argon and the like. The second flow valve 186 may contain one or more flow valves to control the amount and flow rate of the gases into the RPS 164. A controller 178 may be used to achieve desired flow rates for individual gases and the desired hydrogen dilution as described in the methods described herein. The RPS 164 produces ions and radicals of the process gas to facilitate in processing the substrate 114. In some embodiments, plasma is directly generated within the processing volume 108 and used with, for example, diluted hydrogen gas with one or more inert gases to facilitate embodiments of the methods described herein.

A pump port 172 is configured to facilitate removal of particles and gases from the interior volume 102. The chamber 100 is coupled to and in fluid communication with a vacuum system 174. In some embodiments, the vacuum system 174 may include a throttle valve (not shown) and a pump (not shown) which are used to exhaust the chamber 100. In some embodiments, the vacuum system 174 is coupled to the pump port 172 disposed on a bottom surface 176 of the chamber body 106. The pressure inside the chamber 100 may be regulated by adjusting the throttle valve (not shown) and/or vacuum pump (not shown) of the vacuum system 174. In some embodiments, the pump (not shown) of vacuum system 174 has a flow rate of approximately 1900 liters per second to approximately 3000 liters per second. In some embodiments, the vacuum system 174 may be used to at least partially regulate the substrate temperature.

In some embodiments, the controller 178 is used for the operation of the chamber 100. The controller 178 may use direct control of the chamber 100 or alternatively, use indirect control of the chamber 100 by controlling computers (or controllers) associated with the chamber 100. In operation, the controller 178 enables data collection and feedback from the chamber 100 to optimize performance of the chamber 100. The controller 178 generally includes a Central Processing Unit (CPU) 180, a memory 182, and a support circuit 184. The CPU 180 may be any form of a general-purpose computer processor that can be used in an industrial setting. The support circuit 184 is conventionally coupled to the CPU 180 and may comprise a cache, clock circuits, input/output subsystems, power supplies, and the like. Software routines, such as a method as described below may be stored in the memory 182 and, when executed by the CPU 180, transform the CPU 180 into a specific purpose computer (controller 178). The software routines may also be stored and/or executed by a second controller (not shown) that is located remotely from the chamber 100.

The memory 182 is in the form of computer-readable storage media that contains instructions, when executed by the CPU 180, to facilitate the operation of the semiconductor processes and equipment. The instructions in the memory 182 are in the form of a program product such as a program that implements the methods of the present principles. The program code may conform to any one of a number of different programming languages. In some examples, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of embodiments described herein.

During operations with the processing chamber 100, one or more layers or materials are deposited onto the substrate 114 via a deposition operation. During such a deposition operation, gases or plasma may be flowed into (or derived within) the processing volume 108 so as to facilitate the deposition of the one or more layers or materials on the substrate 114. However, as previously described, during these deposition operations, layers of residue are also deposited onto the inner surfaces within the interior volume 102, and particularly within the processing volume 108. In some embodiments, the layers of residue may comprise (at least partially) Molybdenum (Mo). Such films may readily grow or deposit on surfaces within the processing chamber 100 that may comprise metal oxides or nitrides, such as AlOₓ, SiOₓ, and AlN, among others.

The adhesion of deposited residue may be low, and the stress (e.g., compressive stress) exerted on the underlying surface or material by the deposited residue may be high, so that there is an increased risk of residue separation and peeling during subsequent deposition processes in the processing chamber 100 as previously described. For at least some surfaces or components within the processing chamber 100, such as, for instance the showerhead 158, the peeling and separation of the residue may cause the peeled particles to impact the substrate 114 which may result in damage or at least contamination (e.g., metal contamination) of the substrate 114.

Accordingly, embodiments include herein include methods of cleaning and coating the inner surfaces of the processing chamber 100 in order to reduce the risk residue peeling and separation during a subsequent deposition process. As will be described in more detail herein, embodiments of the method 200 may be performed periodically during the operational life of the processing chamber 100 as a preventative measure to reduce a risk of damage or contamination of substrates (e.g., substrate 114) during operations.

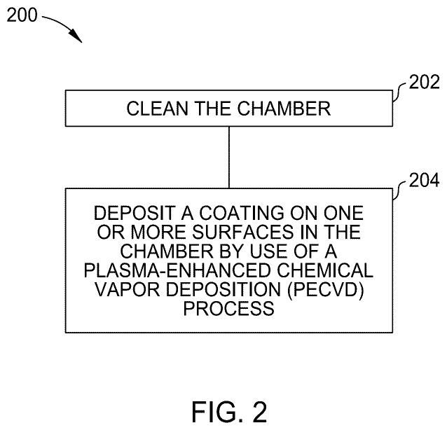

For instance, FIG. 2 shows a flow chart of a method of cleaning and coating the inner surfaces of a processing chamber according to some embodiments disclosed herein. The method 200 illustrated in FIG. 2 may be performed by use of (or for) the processing chamber 100 shown in FIG. 1 according to some embodiments. Thus, in describing the features of the method 200 shown in FIG. 2, continuing reference is made to the processing chamber 100 of FIG. 1. However, it should be appreciated that embodiments of the method 200 may be performed by use of or for processing chambers that are different from the processing chamber 100 of FIG. 1 in at least some respects. Thus, the reference to the processing chamber 100 of FIG. 1 is meant to be illustrative of some embodiments and is not mean to be limiting to other embodiments of the method 200.

In addition, in some embodiments, one or more of the features or operations of the method 200 may be at least partially performed by use of a controller, such as the controller 178 of processing chamber 100 that is previously described herein. Thus, embodiments of the method 200 may be at least partially described or embodied as instructions stored on a non-transitory machine-readable or computer-readable medium (e.g., memory 182) that are executed by a processor (e.g., CPU 180).

In some embodiments, the method 200 may be performed in a processing chamber (such as the processing chamber 100) after a pre-determined number of processing operations on substrates. For instance, in some embodiments, the method 200 may be performed in the processing chamber 100 after about 100 to about 300 substrate depositions processes, such as after about 120 to about 200 substrate deposition processes, or such as after about 200 to about 300 substrate deposition processes. Thus, the method 200 may be periodically and repeatedly performed for a processing chamber in order to lower a risk of metal contamination (due to film peeling as previously described) and to increase the number of cycles between cleanings within the processing chamber. The method 200 may be performed when the processing chamber 100 does not have a substrate positioned (e.g., substrate 114) therein, and the upper surface 146 of the pedestal 116 is fully exposed to the showerhead 158.

Initially, method 200 includes cleaning the chamber at block 202. The cleaning operation of block 202 may be configured to remove (or at least partially remove) accumulated residue within the processing chamber 100. For instance, the cleaning operation of block 20 may remove residue that has been deposited on the inner surfaces of the processing chamber 100 (such as on the inner surfaces defining the processing volume 108) and may remove residue particles that have peeled off from inner surfaces of the processing chamber 100. Specifically, in some embodiments, residue that has peeled off from the showerhead 158 may fall onto the upper surface 146 of pedestal 116, such as during a post-processing purge of the processing chamber 100 after the removal of a substrate 114. The cleaning operation of block 202 may remove not only the accumulated residue on the inner surfaces of the chamber 100 but also these peeled residue particles that are resting on the upper surface 146 of the pedestal 116. Moreover, because the method 200 may be periodically and repeatedly performed during the operational life of the processing chamber 100 as previously described, the cleaning operation of block 202 may also be configured to fully remove (or at least partially remove) a coating that was applied to the inner surfaces of the processing chamber 100 via the coating operation of block 204 (described in more detail herein).

In some embodiments, cleaning the chamber 100 per block 202 may comprise flowing a reactant into the chamber 100, such as into the processing volume 108. In some embodiments, the reactant may comprise a fluoride radical, such as a fluoride radical generated from nitrogen trifluoride (NF₃). In some embodiments, the fluoride radical selectively etches residue deposited on the inner surfaces of the processing chamber 100, such as the process volume 108. In some embodiments, the fluoride radicals are generated from NF₃ thermally within the processing chamber 100 (such as within the processing volume 108). In some embodiments, the fluoride radical is formed by applying an RF bias to the NF₃ (e.g., via the RF power supply 138). Thus, in some embodiments, the cleaning operation of block 202 may comprise applying an RF bias to the substrate support 112, such as to the pedestal 116. In some embodiments, the fluoride radials are generated at radio frequency of about 13.54 MHz. In some embodiments, the fluoride radicals are generated by applying an RF bias in a range of from about 500 W to about 1000 W. In some embodiments, the fluoride radicals may be generated in outside of the processing chamber 100, such as via the RPS 164, and then are subsequently flowed into the processing volume 108 of processing chamber 100 via the showerhead 158.

In some embodiments, the reactant used as part of the cleaning operation of block 202 may comprise a reaction gas. In some embodiments, the reaction gas is flowed into the processing volume 108 at a dose of from 1 liter (L) to about 3 L. In some embodiments, the reaction gas comprises one or more of NF₃, oxygen (O₂), hydrogen (H₂), or argon (Ar), or combinations thereof. For instance, in some embodiments, the reaction gas comprises NF₃ and H₂, with a NF₃:H₂ ratio in a range of about 1:1 to about 1:3. As another example, in some embodiments, the reaction gas comprises NF₃ and O₂, with a NF₃:O₂ ratio in a range of about 1:1 to about 1:3. As still another example, in some embodiments, Ar is co-flowed with one or more of the NF₃, H₂, or O₂.

In some embodiments, the reaction gas further comprises a carrier gas. In some embodiments, the carrier gas comprises an inert gas. In some embodiments, the inert gas flowed with the reaction gas my comprise Ar, helium (He), etc.

Referring still to FIG. 2, the method 200 may also include depositing a coating on one or more surfaces in the chamber by use of a PECVD process at block 204. In some embodiments, the coating operation of block 204 may be performed at the cleaning operation of block 202. In some embodiments, the PEVCD process may comprise injecting a coating precursor (or “precursor”) into the chamber 100 (e.g., such as into the processing volume 108) and reacting the precursor with a plasma within the chamber to deposit a coating on the chamber inner surfaces. In some embodiments, the precursor is a metal-containing precursor so that the coating is a metal-containing coating. Specifically, in some embodiments, the precursor is a Mo-containing precursor, such as molybdenum dichloride dioxide (MoO₂Cl₂) or molybdenum pentachloride (MoCl₅). When reacted with a plasma, such as a hydrogen plasma or hydrogen-based plasma, within the processing chamber, the Mo-containing precursor may form a Mo coating on the chamber inner surfaces that may provide a lower stress on the chamber inner surfaces and improved adhesion to subsequently deposited residue so that a risk of substrate contamination or damage due to residue peeling and separation are reduced.

As previously described, in some embodiments, the method 200, such the operation of block 204 of method 200, may be performed when no substrate (e.g., substrate 114) is present within the on the upper surface 146 of pedestal 116 within the processing chamber 100. Thus, in some embodiments, the surfaces that are coated with the Mo coating per the coating operation of block 204 may particularly include the lower exposed surface of the showerhead 158 and the upper surface 146 of the pedestal 116. Without being limited to this or any other theory, the exposed surfaces of the showerhead 158 within the processing volume 108 (e.g., such as a lower surface of the showerhead 158) may pose a particular risk for falling debris from peeled residue because these surfaces are positioned directly over the substrate 114 during a deposition operation.

In addition, and again without being limited to this or any other theory, the upper surface of the pedestal 116 may directly contact (at least partially) a backside of the substrate 114 during a deposition operation. Thus, the reduced stress and improved adhesion of the coating formed via block 204 may reduce the amount of metals that may become dislodged from the upper surface 146 and transferred to the backside of the substrate 114 during a deposition operation.

In some embodiments, the coating formed on the inner surface of the processing chamber 100 via the coating operation of block 204 may have a thickness that is about 1000 Angstroms (A) or less, such as from about 500 A to about 1000 A, or such as about 600 A. In some embodiments, thicker coatings are contemplated. For instance, in some embodiments, a coating formed on one or more of the inner surfaces of the processing chamber 100 may have a thickness that is between about 1000 A and about 2000 A.

In some embodiments, the coating operation in block 204 may be performed by simultaneously placing plasma, the precursor, and hydrogen in the processing volume 108. Thus, in some embodiments, the plasma, precursor, and hydrogen are not pulsed into the processing volume 108 but are continuously flowed into the processing volume 108 throughout the duration of the coating operation of block 204. In some embodiments, the coating operation may be performed over a period of time that ranges from about 5 seconds to about 100 seconds, such as about 10 seconds to about 90 seconds, such as about 20 seconds to about 80 seconds, such as about 30 seconds to about 70 seconds, or such as about 40 seconds to about 60 seconds.

The plasma, precursor, and hydrogen may all be flowed into the processing volume 108 via the showerhead 158. In some embodiments, the plasma may be remotely generated and/or generated within the processing volume 108, such as by use of the hydrogen that is flowed into the processing volume 108 as previously described. For instance, the plasma may comprise a hydrogen plasma that is generated within the RPS 164 and flowed into the processing volume 108 via the showerhead 158. Additionally, or alternatively, the plasma may be generated within the processing volume 108 via one or more RF power supplies (e.g., such as RF power supplies 138, 166 and/or other RF power supplies). For embodiments in which the plasma is at least partially generated within the processing volume 108, the plasma may be at least partially generated by use of the hydrogen that is flowed into the processing volume 108.

In some embodiments, the precursor may be flowed into the processing volume 108 along or with a carrier gas. In some embodiments, the carrier gas may comprise an inert gas, such as, for instance, argon (Ar). However, other inert carrier gases are contemplated, such as helium (He), nitrogen (N₂), neon (Ne), etc.

In some embodiments, during the coating operation of block 204, the temperature of the pedestal 116 may be in a range of about 250 degrees Celsius (° C.) to about 500° C., such as about 275° C. to about 475° C., such as about 300° C. to about 450° C., such as about 325° C. to about 425 C, or such as from about 350° C. to about 400°C. The temperature of the pedestal 116 may be achieved and maintained by use of a gas channel 144, or by use of another heater or heating element coupled to or embedded within the pedestal 116, or by use of other suitable systems or assemblies.

In some embodiments, during the coating operation of block 204, the pressure in the processing chamber 100, and particularly the pressure in the processing volume 108 may be maintained within a range from about 2.5 Torr to about 30 Torr, such as about 3 Torr to about 25 Torr, such as about 5 Torr to about 20 Torr, such as about 7 Torr to about 15 Torr, or such as about 10 Torr to about 15 Torr. The pressure in the processing volume 108 may be maintained by use of the vacuum system 174 and/or the pressures of the gases emitted into the processing chamber 100, or by use of other suitable systems or assemblies.

In some embodiments, the flow of hydrogen into the processing volume 108 during the coating operation of block 204 may be in a range of from about 500 standard cubic centimeters per minute (sccm) to about 18000 sccm, such as about 1000 sccm to about 15000 sccm, such as about 2000 sccm to about 14000 sccm, such as about 3000 sccm to about 13000 sccm, such as about 4000 sccm to about 12000 sccm, such as about 5000 sccm to about 11000 sccm, such as about 6000 sccm to about 10000 sccm, or such as about 7000 sccm to about 9000 sccm.

In some embodiments, the electrical power for generating the plasma as part of the coating operation in block 204 (e.g., from the RF power supplies 138, 166 and/or other RF power supplies, as previously described) may be in a range of from about 100 Watts (W) to about 1200 W, such as from about 200 W to about 1100 W, such as from about 300 W to about 1000 W, such as from about 300 W to about 900 W, such as from about 400 W to about 800 W, or such as from about 500 W to about 700 W.

In some embodiments, the position of the pedestal 116 may be adjusted within the processing volume 108 (e.g., by the lift actuator 124 shown in FIG. 1) to achieve a suitable spacing between the upper surface 146 of pedestal 116 and the showerhead 158 during the coating operation of block 204. For instance, in some embodiments a spacing, such as a vertical spacing, between the showerhead 158 and the upper surface 146 of the pedestal 116 during the coating operation of block 204 may be in a range of from about 100 mils to about 710 mils, such as about 150 mils to about 650 mils, such as about 200 mils to about 600 mils, such as about 250 mils to about 550 mils, such as about 300 mils to about 500 mils, or such as about 350 mils to about 450 mils.

As previously described, the coating operation of block 204 may result in a coating, such as a Mo coating on one or more (such as all) of the inner surfaces of the processing chamber 100. In particular, the coating operation of block 204 may be result in a Mo coating on the exposed surfaces of the showerhead 158, pedestal 116 (such as upper surface 146), and the inner surfaces of upper shield 148. This Mo coating may comprise a dense film that exerts a reduced stress on the underlying surface as previously described. This reduced stress may help to prevent or at least reduce peeling and separation of later deposited residue that may be deposited on top of the Mo coating as part of subsequent deposition operations within the processing chamber 100. Thus, when the internal surfaces of the processing chamber 100 are coated in the Mo coating as described herein, the processing chamber 100 may perform a greater number of deposition operations on substrates (e.g., substrate 114) before the risk of residue peeling and contamination is sufficient to warrant a further cleaning (e.g., such as is described as part of embodiments of the method 200 shown in FIG. 2). Accordingly, periodic performance of the method 200 may help to increase the time between cleanings for the processing chamber 100 and, as a result, increase a manufacturing throughput of the processing chamber 100.

In some embodiments, the coating operation of block 204 may be performed as a “pre-coating” operation for the inner surfaces of the processing chamber 100 before any substrate processing is performed therein. Thus, in some embodiments, the method 200 may include performance of the coating operation in block 204, and then after a predetermined number of substrate processing operations, the blocks 202 and 204 may be performed in order to clean and re-coat the inner surfaces of the processing chamber 100 as previously described.

As explained above and reiterated below, the present disclosure includes, without limitation, the following Examples.

Example 1: (a) cleaning one or more interior surfaces of a substrate processing chamber; and (b) depositing a coating on the one or more interior surfaces by use of a plasma-enhanced vapor deposition (PECVD) process after (a) to reduce peeling of residue that is subsequently deposited on the coating.

Example 2: The method of any of the Examples, wherein (b) comprises depositing a molybdenum (Mo) coating on the one or more interior surfaces.

Example 3: The method of any of the Examples, wherein (b) further comprises injecting a precursor into the substrate processing chamber, the precursor comprising molybdenum dichloride dioxide (MoO₂Cl₂).

Example 4: The method of any of the Examples, wherein (b) further comprises reacting the precursor with a plasma to form the coating on the one or more interior surfaces, wherein the plasma is at least partially derived from hydrogen.

Example 5: The method of any of the Examples, wherein (b) further comprises depositing the coating on an upper surface of a pedestal of a substrate support that is positioned in the substrate processing chamber.

Example 6: The method of any of the Examples, wherein (b) further comprises depositing the coating so that the coating has a thickness of about 1000 Angstroms (A) or less.

Example 7: The method of any of the Examples, wherein (b) further comprises depositing the coating so that the coating has a thickness in a range of from about 500 A to about 1000 A.

Example 8: The method of any of the Examples, wherein (a) further comprises removing at least some residue that has accumulated on the one or more interior surfaces by exposing the residue to a fluoride radical.

Example 9: The method of any of the Examples, further comprising: (c) after (b), repeating (a) after a predetermined number of substrate deposition processes performed in the substrate processing chamber; and (d) after (c), repeating (b).

Example 10: The method of any of the Examples, wherein (c) further comprises removing the coating that was previously applied to the one or more interior surfaces as part of a previous performance of (b).

Example 11: A method comprising: (a) performing a deposition process in a processing chamber in which a material is deposited onto a surface of a substrate and additional material is deposited on one or more interior surfaces of the processing chamber as residue; (b) removing the substrate from the processing chamber after (a); (c) cleaning the residue off of the one or more interior surfaces by use of a radical after(b); and (d) depositing a coating on the one or more interior surfaces by use of a plasma-enhanced vapor deposition (PECVD) process after (c).

Example 12: The method of any of the Examples, wherein the coating comprises a metal-containing coating, and wherein (d) further comprises depositing the coating on an upper surface of a pedestal of a substrate support in the processing chamber.

Example 13: The method of any of the Examples, wherein the metal-containing coating comprises molybdenum (Mo), and wherein (b) further comprises injecting molybdenum dichloride dioxide (MoO₂Cl₂) as a precursor into the processing chamber.

Example 14: The method of any of the Examples, wherein (a) comprises performing a predetermined number of deposition processes in the processing chamber, wherein the predetermined number of deposition processes comprises between about 100 and about 300 deposition processes.

Example 15: The method of any of the Examples, wherein (d) further comprises depositing the coating so that the coating has a thickness in a range of from about 500 A to about 1000 A.

Example 16: The method of any of the Examples, wherein (d) comprises simultaneously placing the precursor and a plasma in the processing chamber without pulsing either the precursor or the plasma to deposit the coating on the one or more interior surfaces.

Example 17: The method of any of the Examples, wherein (c) further comprises cleaning the residue off of the one or more interior surfaces by use of a fluoride radical.

Example 18: The method of any of the Examples, wherein the fluoride radical comprises nitrogen trifluoride (NF₃).

Example 19: A method comprising: (a) depositing a first molybdenum (Mo) coating on one or more interior surfaces of a processing chamber by use of a first plasma-enhanced vapor deposition (PECVD) process; (b) performing one or more deposition processes in the processing chamber in which a material is deposited onto a surface of a substrate and additional material is deposited on the first Mo coating as a residue; (c) removing the residue and the first Mo coating from the one or more interior surfaces of the processing chamber by use of a radical after (b); and (d) depositing a second Mo coating on the one or more interior surfaces after (c), by use of a second PECVD process.

Example 20: The method of any of the Examples, wherein (a) further comprises depositing the first Mo coating on at least an upper surface of a pedestal of a substrate support and a showerhead positioned in the processing chamber; and wherein (b) further comprises depositing the second Mo coating on at least the upper surface of the pedestal and the showerhead.

Embodiments disclosed herein include methods for cleaning and coating the internal surfaces of a substrate processing chamber in order to reduce the risk of damage or contamination of a substrate due to peeling of residue deposited thereon. In some embodiments, a method described herein may include performing a cleaning operation within the processing chamber following a number of deposition operations for substrate. The cleaning operation may be configured to remove at least a portion (or all) of the residue that may have been deposited on the inner surface within the processing chamber during previous deposition operations. Following the cleaning operation, embodiments of the methods described herein may include coating the inner surfaces of the processing chamber via a plasma enhanced chemical vapor deposition (PECVD) process. In some embodiments, the coating formed by the PECVD process may exert a lower stress on the underlying surface or material so that subsequently deposited residue on the coating is less likely to peel and therefore cause damage or contamination to a substrate undergoing a deposition process in the processing chamber. Thus, through use of the embodiments disclosed herein, the risk of damage or contamination resulting from peeled residue in a substrate processing chamber may be reduced. In addition, embodiments disclosed herein may allow a substrate processing chamber to perform a greater number of deposition operations before an additional cleaning and coating operation according to the embodiments described herein is to be performed.

The preceding discussion is directed to various embodiments. However, one of ordinary skill in the art will understand that the examples disclosed herein have broad application, and that the discussion of any embodiment is meant only to be exemplary of that embodiment and is not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the preceding discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

While exemplary embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. Accordingly, the scope of protection is not limited to the embodiments described herein, but is only limited by the claims that follow, the scope of which shall include all equivalents of the subject matter of the claims. Unless expressly stated otherwise, the operations in a method claim may be performed in any order. The recitation of identifiers such as (a), (b), (c) or (1), (2), (3) before operations in a method claim are not intended to and do not specify a particular order to the operations, but rather are used to simplify subsequent reference to such operations.

What is claimed is:

1. A method comprising:
(a) cleaning one or more interior surfaces of a substrate processing chamber; and
(b) depositing a coating on the one or more interior surfaces by use of a plasma-enhanced vapor deposition (PECVD) process after (a) to reduce peeling of residue that is subsequently deposited on the coating.

2. The method of claim 1, wherein (b) comprises depositing a molybdenum (Mo) coating on the one or more interior surfaces.

3. The method of claim 2, wherein (b) further comprises injecting a precursor into the substrate processing chamber, the precursor comprising molybdenum dichloride dioxide (MoO₂Cl₂).

4. The method of claim 3, wherein (b) further comprises reacting the precursor with a plasma to form the coating on the one or more interior surfaces, wherein the plasma is at least partially derived from hydrogen.

5. The method of claim 4, wherein (b) further comprises depositing the coating on an upper surface of a pedestal of a substrate support that is positioned in the substrate processing chamber.

6. The method of claim 4, wherein (b) further comprises depositing the coating so that the coating has a thickness of about 1000 Angstroms (A) or less.

7. The method of claim 6, wherein (b) further comprises depositing the coating so that the coating has a thickness in a range of from about 500 A to about 1000 A.

8. The method of claim 4, wherein (a) further comprises removing at least some residue that has accumulated on the one or more interior surfaces by exposing the residue to a fluoride radical.

9. The method of claim 4, further comprising:
(c) after (b), repeating (a) after a predetermined number of substrate deposition processes performed in the substrate processing chamber; and
(d) after (c), repeating (b).

10. The method of claim 9, wherein (c) further comprises removing the coating that was previously applied to the one or more interior surfaces as part of a previous performance of (b).

11. A method comprising:
(a) performing a deposition process in a processing chamber in which a material is deposited onto a surface of a substrate and additional material is deposited on one or more interior surfaces of the processing chamber as residue;
(b) removing the substrate from the processing chamber after (a);
(c) cleaning the residue off of the one or more interior surfaces by use of a radical after(b); and
(d) depositing a coating on the one or more interior surfaces by use of a plasma-enhanced vapor deposition (PECVD) process after (c).

12. The method of claim 11, wherein the coating comprises a metal-containing coating, and wherein (d) further comprises depositing the coating on an upper surface of a pedestal of a substrate support in the processing chamber.

13. The method of claim 12, wherein the metal-containing coating comprises molybdenum (Mo), and wherein (b) further comprises injecting molybdenum dichloride dioxide (MoO₂Cl₂) as a precursor into the processing chamber.

14. The method of claim 13, wherein (a) comprises performing a predetermined number of deposition processes in the processing chamber, wherein the predetermined number of deposition processes comprises between about 100 and about 300 deposition processes.

15. The method of claim 14, wherein (d) further comprises depositing the coating so that the coating has a thickness in a range of from about 500 A to about 1000 A.

16. The method of claim 15, wherein (d) comprises simultaneously placing the precursor and a plasma in the processing chamber without pulsing either the precursor or the plasma to deposit the coating on the one or more interior surfaces.

17. The method of claim 16, wherein (c) further comprises cleaning the residue off of the one or more interior surfaces by use of a fluoride radical.

18. The method of claim 17, wherein the fluoride radical comprises nitrogen trifluoride (NF₃).

19. A method comprising:
(a) depositing a first molybdenum (Mo) coating on one or more interior surfaces of a processing chamber by use of a first plasma-enhanced vapor deposition (PECVD) process;
(b) performing one or more deposition processes in the processing chamber in which a material is deposited onto a surface of a substrate and additional material is deposited on the first Mo coating as a residue;
(c) removing the residue and the first Mo coating from the one or more interior surfaces of the processing chamber by use of a radical after (b); and
(d) depositing a second Mo coating on the one or more interior surfaces after (c), by use of a second PECVD process.

20. The method of claim 19, wherein (a) further comprises depositing the first Mo coating on at least an upper surface of a pedestal of a substrate support and a showerhead positioned in the processing chamber; and wherein (b) further comprises depositing the second Mo coating on at least the upper surface of the pedestal and the showerhead.
